(19) United States
(12) Patent Application Publication
(10) Pub. No.: US 2016/0338227 A1
(43) Pub. Date: Nov. 17, 2016

(54) LOW PROFILE HEAT SINK

(71) Applicant: Adtran, Inc., Huntsville, AL (US)

(72) Inventors: Robert A. Saluski, Black Canyon City, AZ (US); Nirmal S. Virdee, Peoria, AZ (US)

(21) Appl. No.: 14/708,341

(22) Filed: May 11, 2015

(51) Int. Cl. H05K 7/20

(52) U.S. Cl. CPC H05K 7/20409

(57) ABSTRACT

A heat sink includes a heat sink body having a central portion and at least a first extended portion, and heat dissipation elements extending from at least the first extended portion, the heat dissipation elements extending no further than a plane formed by an upper surface of the central portion, the central portion having a recess configured to receive a heat generating element, the central portion being free of heat dissipation elements.

### BACKGROUND

In many communication applications and installations, an enclosure, sometimes referred to a chassis or a card cage, is used to house a number of communication modules. A card cage typically has a main circuit board, referred to as a “backplane” to which the communication modules electrically connect. The card cage also typically has a mechanical mounting arrangement into which the individual communication modules engage. A typical communication module may have a modular structure, and in many cases includes components that are fabricated on a printed wiring board (PWB), a printed circuit board (PCB), or another substrate. The card cage typically houses more than one communication module, and in many cases, houses tens of communication modules. In a typical application, the communication modules are loaded into the card cage so that they nearly adjoin each other. Such an arrangement leads to space restrictions, and typically leads to height limitations for components mounted on the PWB. Such height limitations further compound the difficulty of cooling the circuits and modules that are mounted on the PWB.

For example, there is typically at least one, and usually more than one, heat generating element on a communication module located on a PWB that requires some form of cooling. A typical cooling element is referred to as a heat sink. A heat sink can be any structure that removes heat from a heat generating element. A typical heat sink can be fabricated from copper, aluminum, an aluminum alloy, or another metal or material having high heat transfer ability, and is typically located directly over a heat generating element, such that the heat is conducted away from the heat generating element. However, other forms of cooling, using for example, convection, or a combination of conduction and convection are possible. In many applications, the height limitations and packaging density of the circuits and modules may also limit the amount of airflow over a top surface of a heat sink, further complicating heat removal from a heat generating element.

The above-mentioned height limitations typically make it difficult to integrate a traditional heat sink on top of a heat generating element. Therefore, it would be desirable to have a way of cooling a heat generating element on a communications module, or any electronic circuit, where there is a height limitation.

### SUMMARY

An embodiment of a heat sink includes a heat sink body having a central portion and at least a first extended portion, and heat dissipation elements extending from at least the first extended portion, the heat dissipation elements extending no further than a plane formed by an upper surface of the central portion, the central portion having a recess configured to receive a heat generating element, the central portion being free of heat dissipation elements.

Another embodiment of a heat sink includes a heat sink body having a central portion, a first extended portion, a second extended portion, and heat dissipation elements extending from a surface of the first extended portion and a surface of the second extended portion, the central portion having a recess configured to receive a heat generating element, the central portion being free of heat dissipation elements.

Other embodiments are also provided. Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

Exemplary embodiments of the invention can be better understood with reference to the following figures. The components within the figures are not necessarily to scale, emphasis instead being placed upon clearly illustrating the principles of the invention. Moreover, in the figures, like reference numerals designate corresponding parts throughout the different views.

FIG. 1 is a diagram showing the profile of a heat sink in accordance with an exemplary embodiment.

FIG. 2 is a diagram showing a plan view of the heat sink of FIG. 1.

FIG. 3A is a diagram showing exemplary airflow over and around the profile of the heat sink of FIG. 1.

FIG. 3B is a diagram showing exemplary airflow over and around the plan view of the heat sink of FIG. 2.

FIG. 4 is a diagram showing the heat sink of FIG. 1 located over a printed wiring board.

FIG. 5 is a flow chart describing the operation of an embodiment of a method for removing heat.

FIG. 6 is a diagram showing a plan view of an alternative embodiment of the heat sink of FIGS. 1 and 2.

FIG. 7 is a diagram showing airflow over and around a plan view of the heat sink of FIG. 6.

FIG. 8 is a diagram showing a plan view and airflow over and around an alternative embodiment of the heat sink of FIGS. 1 and 2.

FIG. 9 is a diagram showing a plan view and airflow over and around an alternative embodiment of the heat sink of FIGS. 1 and 2.

FIG. 10 is a diagram showing a plan view and airflow over and around an alternative embodiment of the heat sink of FIGS. 1 and 2.

FIG. 11 is a diagram showing a plan view and airflow over and around an alternative embodiment of the heat sink of FIGS. 1 and 2.

### DETAILED DESCRIPTION

Many electronic devices include one or more heat generating devices or elements. For example, an optical module, a communication module, a processor, an application specific integrated circuit (ASIC), or many other electronic devices generate heat during their operation. Managing, or removing, the generated heat is becoming more and more difficult given the smaller and smaller package sizes of electronic modules in which these heat generating elements are incorporated. For example, communication modules are often located in a card cage arrangement in which multiple modules are oriented side to side, top to bottom, or otherwise nearly adjoining each other. Because it is desirable to minimize the height, or thickness, of such communication modules, often there is insufficient space above a heat generating element in which to locate a conventional heat sink or provide airflow over the heat generating element. Although described with particular reference to an optical module or a communication module, embodiments of the heat sink described herein can be used in any electronic module in which it is desirable to remove heat from a heat generating element and minimize the overall thickness or height of the module.

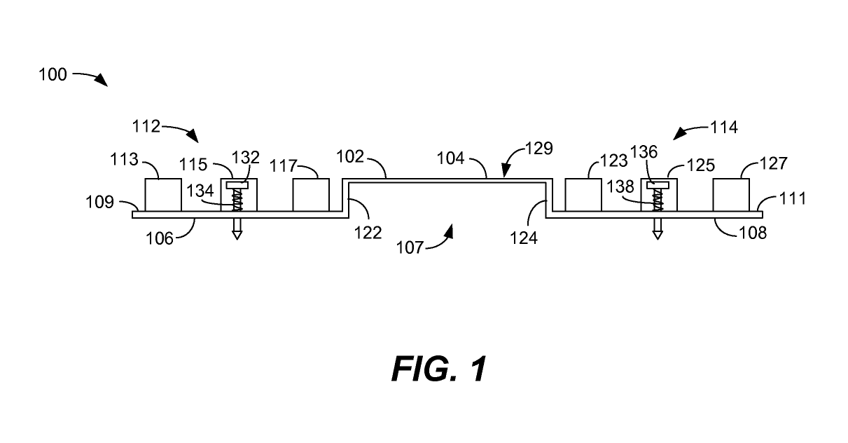

FIG. 1 is a diagram showing the profile of a heat sink in accordance with an exemplary embodiment. In an exemplary embodiment, the heat sink 100 generally comprises a body 102 having a central portion 104 and extended portions 106 and 108. The central portion 104 can be connected to the extended portion 106 by side wall 122, and the central portion 104 can be connected to the extended portion 108 by side wall 124. Although illustrated as having two extended portions 106 and 108 in FIG. 1, it is also understood that a heat sink in accordance with exemplary embodiments described herein can have as few as one or more than two extended portions. Further, although illustrated as having two side walls 122 and 124 in FIG. 1, it is also understood that a heat sink in accordance with exemplary embodiments described herein can have as few as one or more than two side walls. In an exemplary embodiment, the body 102 can be formed or fabricated using a metal having a relatively high heat transfer ability, such as aluminum, an aluminum alloy, copper, a copper alloy, or other material having high heat transfer ability. Other metals and other materials having a relatively high heat transfer ability can also be used to fabricate the heat sink 100. The central portion 104 can be formed so as to create a recess 107. The recess 107 can be configured to accommodate a heat generating element (not shown in FIG. 1), or a module cage (not shown in FIG. 1) that may accommodate a heat generating element. In an exemplary embodiment, the body 102 comprising the central portion 104, the side walls 122 and 124, and the extended portions 106 and 108 (and the corresponding elements of the alternative embodiments of the heat sink described herein) may be formed as a single unitary structure or as separate elements that may be coupled together.

The extended portion 106 comprises heat dissipation elements 112 and the extended portion 108 comprises heat dissipation elements 114. The heat dissipation elements 112 comprise exemplary heat dissipation elements 113, 115 and 117. The heat dissipation elements 114 comprise exemplary heat dissipation elements 123, 125 and 127. The heat dissipation elements 113, 115 and 117 and the heat dissipation elements 123, 125 and 127 can be formed as curved elements, each having one or more different profiles, as will be described below. However, the heat dissipation elements can be fabricated using other structures, such as pins, posts or other structures having other shapes and/or profiles. In an exemplary embodiment, the heat dissipation elements 113, 115 and 117 extend upwardly from the surface 109 of the extended portion 106, and the heat dissipation elements 123, 125 and 127, extend upwardly from the surface 111 of the extended portion 108. In an exemplary embodiment, the upper ends of the heat dissipation elements 113, 115 and 117 and the upper ends of the heat dissipation elements 123, 125 and 127 extend no further than a plane defined by the top surface 129 of the central portion 104. In other words, the upper ends of the heat dissipation elements 113, 115 and 117 and the upper ends of the heat dissipation elements 123, 125 and 127 extend no further than the top surface 129 of the central portion 104. As used herein, the terms “upwardly” and “extend upwardly” when referring to the heat dissipation elements 112 and the heat dissipation elements 114 are intended to refer to the extending of the heat dissipation elements 112 and the heat dissipation elements 114 toward the plane defined by the top surface 129 of the central portion 104 and are intended to be spatially invariant. For example, if the heat sink 100 were rotated 90 degrees, then the heat dissipation elements 112 and the heat dissipation elements 114 would extend sideways, but no further than the plane defined by the top surface 129 of the central portion 104. In an exemplary embodiment, the top surface 129 of the central portion 104 is free of heat dissipation elements so as to minimize the overall height of the central portion 104. In an exemplary embodiment in which the body 102 comprising the central portion 104, the side walls 122 and 124, and the extended portions 106 and 108 may be formed as a single unitary structure, the various embodiments of the heat dissipation elements 112 and the heat dissipation elements 114 described herein may also be unitarily formed as part of the same unitary structure from which the body 102 is formed.

A fastener 132 having a biasing element 134 can be located through the extended portion 106, and a fastener 136 having a biasing element 138 can be located through the extended portion 108. The biasing element 134 and the biasing element 138 can be, for example, a spring configured to apply downward pressure on the heat sink 100 when the heat sink 100 is located over a substrate, such as a printed circuit board (PCB), a printed wiring board (PWB) or another substrate, as will be described below. In an exemplary embodiment, the biasing element 134 and the biasing element 138 can be configured to apply downward pressure on the heat sink 100 when the heat sink 100 is located over a heat generating element and fastened to a substrate, such as a printed circuit board (PCB), a printed wiring board (PWB) or another substrate, as will be described below. However, the biasing element 134 and the biasing element 138 can be other structures configured to exert downward pressure on the heat sink 100 when the heat sink 100 is located over a substrate, such as a printed circuit board (PCB), a printed wiring board (PWB) or another substrate, regardless of whether a heat generating element is located on the printed circuit board (PCB), printed wiring board (PWB) or another substrate.

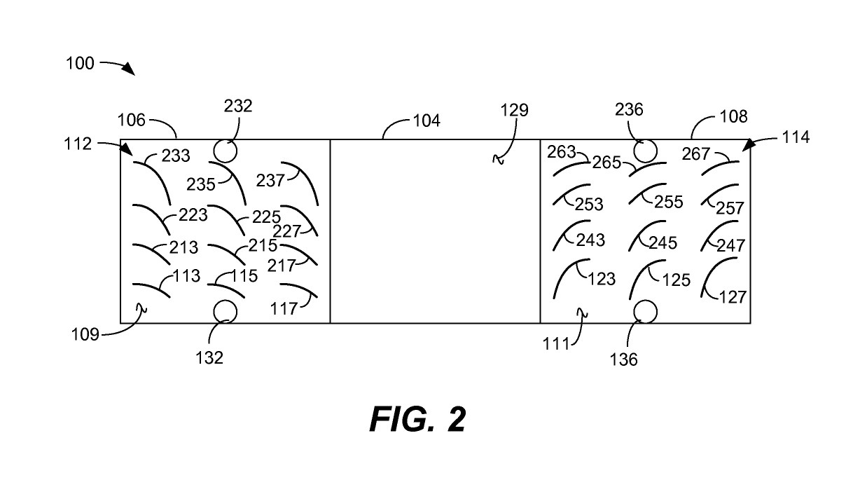

FIG. 2 is a diagram showing a plan view of the heat sink of FIG. 1. The heat sink 100 comprises an additional fastener 232 located through the extended portion 106, and an additional fastener 236 located through the extended portion 108. The fastener 232 and the fastener 236 each comprise a biasing element (not shown) similar to the biasing elements 134 and 138 (FIG. 1).

In an exemplary embodiment, the heat dissipation elements 113, 115 and 117 can have the same shape or can have different shapes. Similarly, in an exemplary embodiment, the heat dissipation elements 123, 125 and 127 can have the same shape or can have different shapes. In an exemplary embodiment, the heat sink 100 also comprises heat dissipation elements 213, 215 and 217, heat dissipation elements 223, 225 and 227, and heat dissipation elements 233, 235 and 237, extending upwardly from the surface 109 of the extended portion 106. Similarly, in an exemplary embodiment, the heat sink 100 also comprises heat dissipation elements 243, 245 and 247, heat dissipation elements 253, 255 and 257, and heat dissipation elements 263, 265 and 267, extending upwardly from the surface 111 of the extended portion 108.

In an exemplary embodiment, the heat dissipation elements 113, 115 and 117 have the same shape, the heat dissipation elements 213, 215 and 217 have the same shape, the heat dissipation elements 223, 225 and 227 have the same shape, and the heat dissipation elements 233, 235 and 237 have the same shape.

In an exemplary embodiment, the heat dissipation elements 112 and 114 are implemented as curved elements, sometimes referred to as “fins.” In another exemplary embodiment, the heat dissipation elements 112 and 114 are implemented as curved elements having curves of different shape. In another exemplary embodiment, the heat dissipation elements 112 and 114 are implemented as a plurality of curved elements configured in rows or columns having multiple curved elements having the same shape. In another exemplary embodiment, the heat dissipation elements 112 and 114 are implemented as a plurality of curved elements configured in more than one row or column, each row or column having multiple curved elements having the same shape, but a shape different than the shape of the elements in another row or column. Each heat dissipation element may be similar in shape, or each heat dissipation element may be shaped differently from each other heat dissipation element. Moreover, each heat dissipation element may be a shape other than a fin, such as, for example, a pin, a post, or any other shape that can be used to conduct heat and direct airflow across the heat dissipation elements and around the central portion 104. The term “direct airflow” refers to the ability of a structure or a plurality of structures, to influence the flow of air through, around, or otherwise in the vicinity of the structure or plurality of structures.

In an exemplary embodiment, the heat dissipation elements 123, 125 and 127 have the same shape, the heat dissipation elements 243, 245 and 247 have the same shape, the heat dissipation elements 253, 255 and 257 have the same shape, and the heat dissipation elements 263, 265 and 267 have the same shape. However, the heat dissipation elements may have different shapes than that described herein. In an exemplary embodiment, the shape, location, orientation, structure and other physical attributes of the heat dissipation elements 112 and 114 can be configured to direct, promote and maximize airflow across the heat dissipation elements and around the central portion 104 to aid in removing heat from the central portion 104 when airflow across the upper surface 129 may be impeded. The shape of each heat dissipation element may be optimized to maximize heat dissipation and maximize cooling with the available airflow. In an exemplary embodiment, the upper ends of the heat dissipation elements 112 and the heat dissipation elements 114 extend no further than the plane defined by the top surface 129 of the central portion 104.

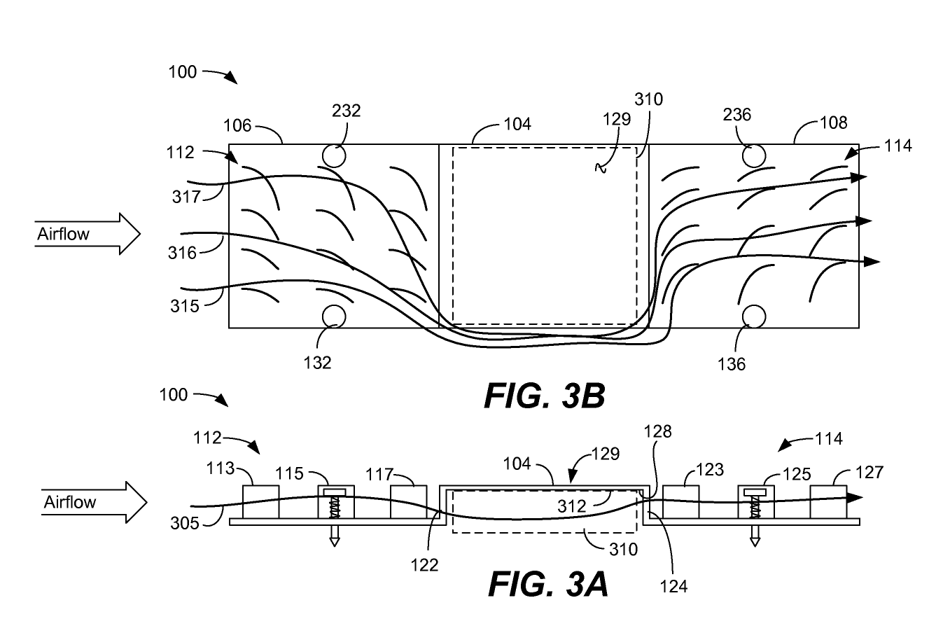

FIG. 3A is a diagram showing exemplary airflow over and around the profile of the heat sink of FIG. 1. In an implementation where the upper surface 129 of the heat sink 100 may abut, or be located very close to another module or other structure, airflow across the upper surface 129 of the heat sink 100 may be severely restricted, or impeded. The bold arrow 305 illustrates airflow that can be directed across and around portions of the heat sink 100 at least in part by the heat dissipation elements 112 and 114. In an exemplary embodiment, one or more of the shape, profile and location of the heat dissipation elements 112 and one or more of the shape, profile and location of the heat dissipation elements 114 causes air to flow through the heat dissipation elements 112, around the central portion 104, and through the heat dissipation elements 114. An exemplary heat generating element 310 is shown for example of illustration. The heat generating element 310 can be an optical module, a communication module, a processor, an ASIC, a controller, or any other heat generating element. The upper surface 312 of the heat generating element 310 can be in contact with, or in near-contact with the undersurface 128 of the central portion 104. Heat generated by the heat generating element 310 is transferred to the central portion 104 through this contact or near-contact with the undersurface 128. As a result of the heat transfer properties of the heat sink 100, heat is conductively transferred to the heat dissipation elements 112 and to the heat dissipation elements 114 via sidewalls 122 and 124, respectively, and via extended portions 106 (FIGS. 1) and 108 (FIG. 1). As a result of the heat transfer properties of the heat sink 100, heat is also conductively transferred from the undersurface 128 to the upper surface 129 of the central portion 104 and then transferred via the sidewalls 122 and 124, respectively, to the extended portions 106 (FIGS. 1) and 108 (FIG. 1) to the heat dissipation elements 112 and 114. The air passing through the heat dissipation elements 112, around the central portion 104, and through the heat dissipation elements 114 removes this heat and therefore cools the central portion 104, in turn removing heat from the heat generating element 310. In an exemplary embodiment, the heat dissipation elements 112 and 114 are located to promote airflow through the heat dissipation elements 112, around the central portion 104, and then through the heat dissipation elements 114 such that even if air is impeded or prevented from flowing over the upper surface 129, air still flows through the heat dissipation elements 112 and 114, thus maximizing the transfer of heat away from the heat generating element 310. In an exemplary embodiment, the heat dissipation elements 112 and 114 are located spaced away from the heat generating element 310 and extend upwardly no further than a plane defined by the upper surface 129 of the central portion 104. In an exemplary embodiment, the heat dissipation elements 112 and 114 maintain indirect contact with the heat generating element 310 in that the heat dissipation elements 112 and 114 do not directly contact or emanate from any surface of the heat generating element 310.

FIG. 3B is a diagram showing airflow over and around a plan view of the heat sink of FIG. 2. The bold arrows 315, 316 and 317 illustrate airflow that can be directed across the heat sink 100 and around the central portion 104 by the heat dissipation elements 112 and 114. In an exemplary embodiment, the shape, location, orientation, structure and other physical attributes of the heat dissipation elements 112 and the heat dissipation elements 114 causes air to flow through the heat dissipation elements 112, around the central portion 104, and through the heat dissipation elements 114. The airflow can be as a result of forced air, such as from a cooling fan, or can be convective air flow caused by thermal differences in the vicinity of the heat sink 100.

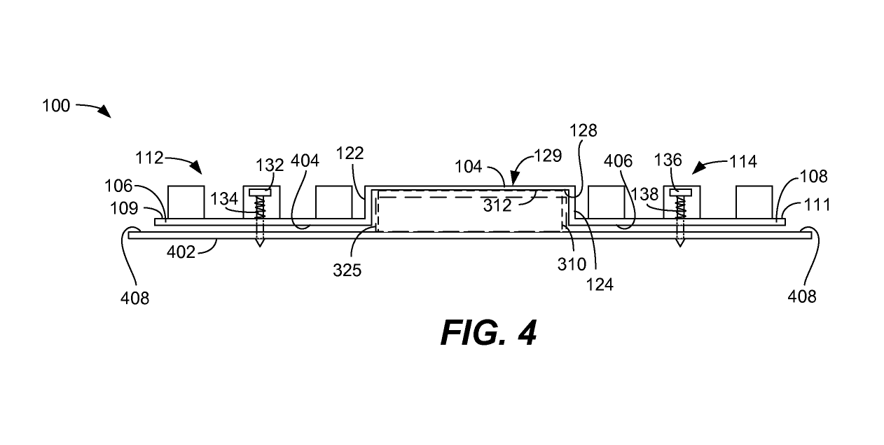

FIG. 4 is a diagram showing the heat sink of FIG. 1 located over a printed wiring board (PWB). In an exemplary embodiment, the fasteners 132, 136, 232 (not shown) and 236 (not shown) can be configured to secure the heat sink 100 to a printed wiring board (PWB) 402. In an exemplary embodiment, the heat generating element 310 is configured to fit within the recess 107 (FIG. 1) of the heat sink 100, and is also configured to fit within a module cage 325. In an exemplary embodiment, the module cage 325 houses the heat generating element 310, and fits within the recess 107 (FIG. 1) such that the upper surface 312 of the heat generating element 310 and at least two opposing sides of the heat generating element 310 are substantially covered by the heat sink 100. In alternative embodiments, only the upper surface 312 and one side of the heat generating element 310 may be substantially covered by the heat sink 100. The biasing elements 134 and 138, and the biasing elements (not shown) of the fasteners 232 (not shown) and 236 (not shown) are configured to exert a downward pressure on the surfaces 109 and 111 of the heat sink 100, thereby allowing the heat sink 100 to “float” above the PWB 402, and thereby encouraging contact between the upper surface 312 of the heat generating element 310 and the undersurface 128 of the central portion 104. In this manner, heat transfer from the upper surface 312 of the heat generating element 310 to the undersurface 128 of the central portion 104 and to the heat dissipation elements 112 and 114, via the sidewalls 122 and 124, respectively, and via the extended portions 106 and 108, respectively, is maximized Maximizing the transfer of heat from the heat generating element 310 to the undersurface 128 of the central portion 104 thereby maximizes heat transfer from the heat dissipation elements 112 and 114 to air passing through the heat dissipation elements 112 and 114 (FIG. 3B), and maximizes heat transfer from the upper surface 129 of the central portion 104 to the extended portions 106 (FIGS. 1) and 108 (FIG. 1).

The biasing elements 134 and 138, and the biasing elements (not shown) of the fasteners 232 (not shown) and 236 (not shown) that allow the heat sink 100 to “float” above the PWB 402 also allow the insertion and removal of a heat generating element 310 without removing the heat sink 100 from the PWB 402. For example, in the absence of a heat generating element 310, the biasing elements 134 and 138, and the biasing elements (not shown) of the fasteners 232 (not shown) and 236 (not shown) exert a downward pressure on the heat sink 100 such that the surface 404 of the extended portion 106 contacts the surface 408 of the PCB 402; and the surface 406 of the extended portion 108 contacts the surface 408 of the PCB 402. To insert a heat generating element 310, the heat sink 100 can be lifted to overcome the downward pressure of the biasing elements 134 and 138, and the biasing elements (not shown) of the fasteners 232 (not shown) and 236 (not shown) to allow a heat generating element 310 to be inserted under or into the recess 107 of the heat sink without removing the heat sink 100 from the PCB 402.

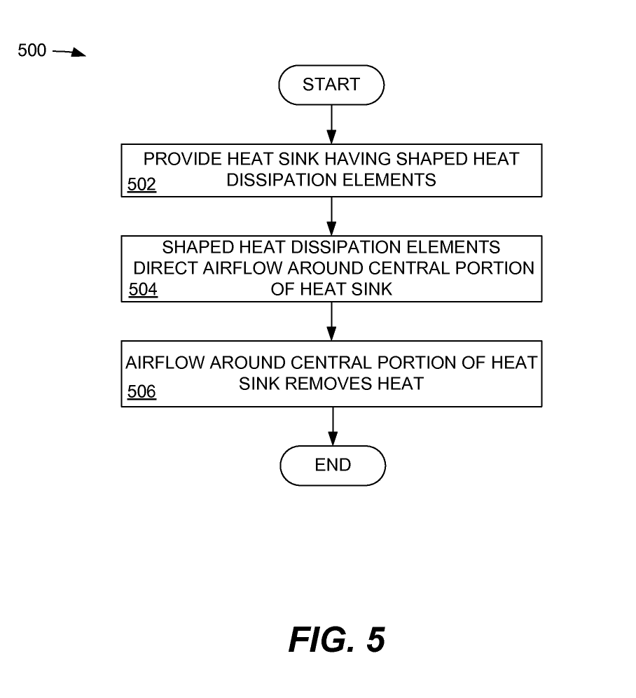

FIG. 5 is a flow chart describing the operation of an embodiment of a method for removing heat. The steps in the flow chart 500 can be performed in or out of the order shown, and in some instances, may be performed in parallel.

In block 502, a heat sink having shaped heat dissipation elements is provided.

In block 504, the shaped heat dissipation elements direct airflow around a surface of the heat sink. In an exemplary embodiment, the shaped heat dissipation elements direct airflow through the heat dissipation elements and around a central portion of the heat sink.

In block 506, the airflow across the heat dissipation elements and around the central portion of the heat sink removes heat from the heat sink and from a heat generating element.

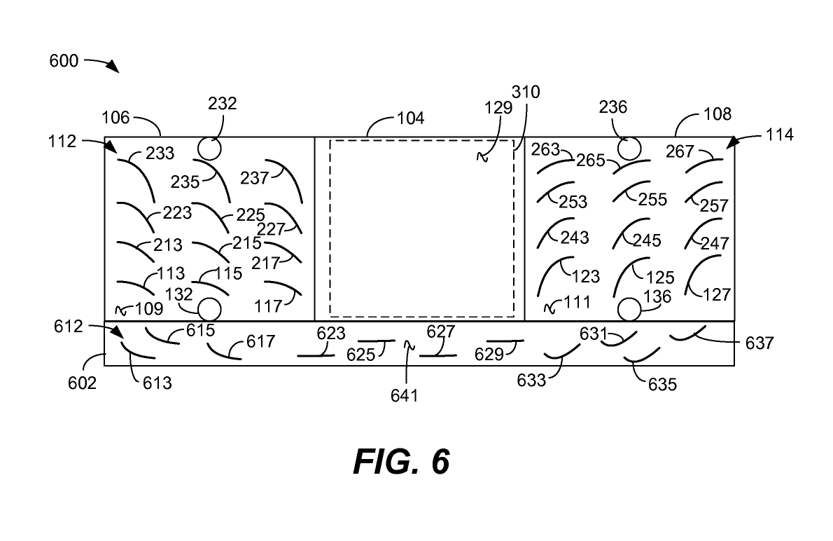

FIG. 6 is a diagram showing a plan view of an alternative embodiment of the heat sink of FIGS. 1 and 2. The heat sink 600 is similar to the heat sink 100 of FIGS. 1 and 2, but includes an additional extended portion 602 having heat dissipation elements 612. The additional portion 602 may comprise heat dissipation elements 612 that can be shaped to further direct and influence the airflow around the central portion 104. In an exemplary embodiment, the heat dissipation elements 613, 615 and 617 can have the same shape or can have different shapes. Similarly, in an exemplary embodiment, the heat dissipation elements 623, 625, 627 and 629 can have the same shape or can have different shapes; and the heat dissipation elements 631, 633, 635 and 637 can have the same shape or can have different shapes. The heat dissipation elements 613, 615, 617, 623, 625, 627, 629, 631, 633, 635 and 637 can extend upwardly from the surface 641 of the additional extended portion 602, no further than the plane defined by the upper surface 129 of the central portion 104.

In an exemplary embodiment, the heat dissipation elements 612 can be similar to the heat dissipation elements 112 and 114 in that they may have any shape, location, orientation, structure and other physical attribute that maximizes cooling of a heat generating element located in contact with the central portion 104 of the heat sink 600.

In an exemplary embodiment, the shape of the heat dissipation elements 112, 114 and 612 can be configured to promote airflow across the heat dissipation elements 112, 114 and 612, and around the central portion 104 to aid in removing heat from the central portion 104 when airflow across the upper surface 129 may be impeded. The shape, location, orientation, structure and other physical attributes of each heat dissipation element may be optimized to maximize airflow and heat dissipation. Each heat dissipation element may be similar in shape, or each heat dissipation element may be shaped differently than other heat dissipation elements. Moreover, each heat dissipation element may be a shape other than a fin, such as, for example, a pin, a post, an elongated plane, or any other shape that can be used to direct airflow across the heat dissipation elements 112, 114 and 612, and around the central portion 104.

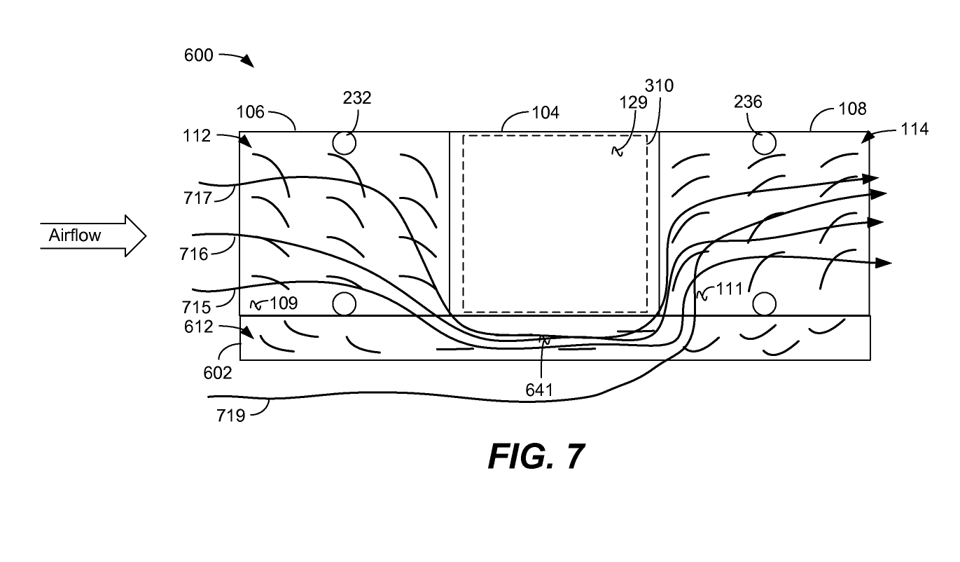

FIG. 7 is a diagram showing airflow over and around a plan view of the heat sink of FIG. 6. The bold arrows 715, 716 and 717 illustrate airflow that can be directed across the heat sink 100 and around the central portion 104 by the heat dissipation elements 112, 114 and 612. In an exemplary embodiment, the shape, location, orientation, structure and other physical attributes of the heat dissipation elements 612 direct the airflow from the heat dissipation elements 112 closely around the central portion 104 and then toward the heat dissipation elements 114 causing air to flow through the heat dissipation elements 112, around the central portion 104, through the heat dissipation elements 612 and through the heat dissipation elements 114. Moreover, at least a portion of the heat dissipation elements 612 can also cause air that may not be directed toward the heat dissipation elements 112, such as air flow shown by the bold arrow 719, to be directed toward and then through the heat dissipation elements 114. This additional airflow directed by the heat dissipation elements 612 can further improve cooling provided by the heat sink 600. The airflow can be as a result of forced air, such as from a cooling fan, or can be convective air flow caused by thermal differences in the vicinity of the heat sink 600

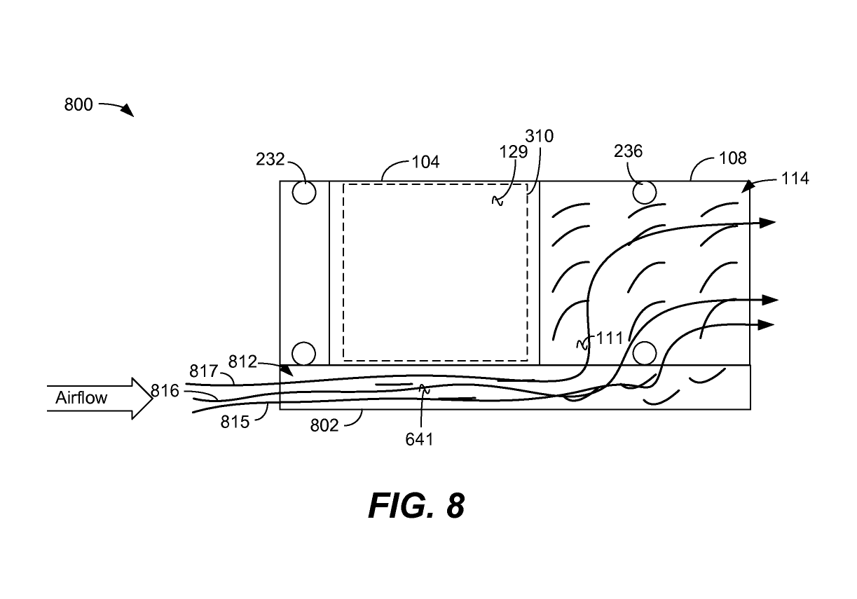

FIG. 8 is a diagram showing a plan view and airflow over and around an alternative embodiment of the heat sink of FIGS. 1 and 2. The heat sink 800 is similar to the heat sink 600 shown in FIGS. 6 and 7. However, the heat sink 800 comprises extended portion 108 and extended portion 802. Extended portion 802 is similar to extended portion 602, but extended portion 802 comprises heat dissipation elements 812, which are a portion of the heat dissipation elements 612 of the heat sink 600. In the embodiment shown in FIG. 8, exemplary airflow is depicted using bold arrows 815, 816 and 817, and illustrates airflow being directed by the heat dissipation elements 812 around the central portion 104 and then through the heat dissipation elements 114 to remove heat from the heat generating element 310.

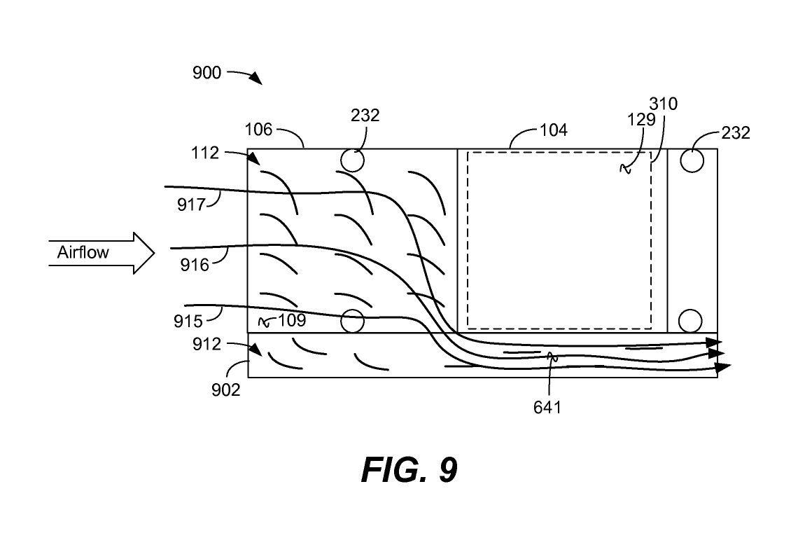

FIG. 9 is a diagram showing a plan view and airflow over and around an alternative embodiment of the heat sink of FIGS. 1 and 2. The heat sink 900 is similar to the heat sink 600 shown in FIGS. 6 and 7. However, the heat sink 900 comprises extended portion 106 and extended portion 902. Extended portion 902 is similar to extended portion 602, but extended portion 902 comprises heat dissipation elements 912, which are a portion of the heat dissipation elements 612 of the heat sink 600. In the embodiment shown in FIG. 9, exemplary airflow is depicted using bold arrows 915, 916 and 917, and illustrates airflow being directed by the heat dissipation elements 112 to the heat dissipation elements 912 around the central portion 104 to remove heat from the heat generating element 310.

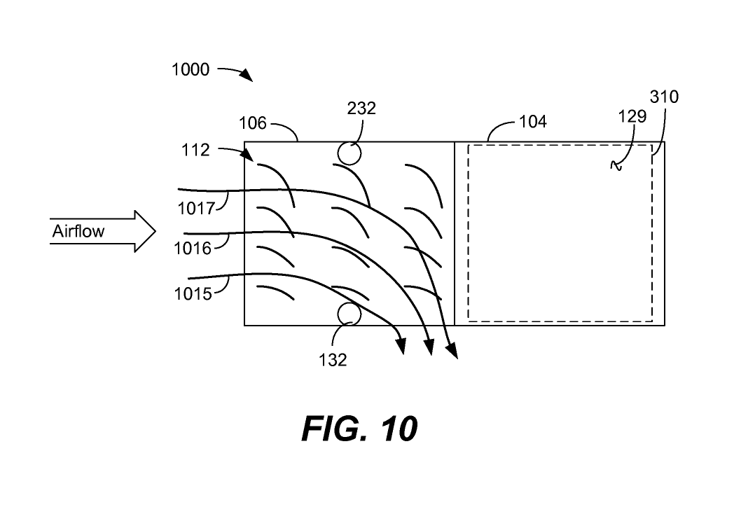

FIG. 10 is a diagram showing a plan view and airflow over and around an alternative embodiment of the heat sink of FIGS. 1 and 2. The heat sink 1000 is similar to the heat sink 600 shown in FIGS. 6 and 7. However, the heat sink 1000 comprises extended portion 106. In the embodiment shown in FIG. 10, exemplary airflow is depicted using bold arrows 1015, 1016 and 1017, and illustrates airflow being directed across the heat dissipation elements 112 and being directed by the heat dissipation elements 112 around the central portion 104 to remove heat from the heat generating element 310.

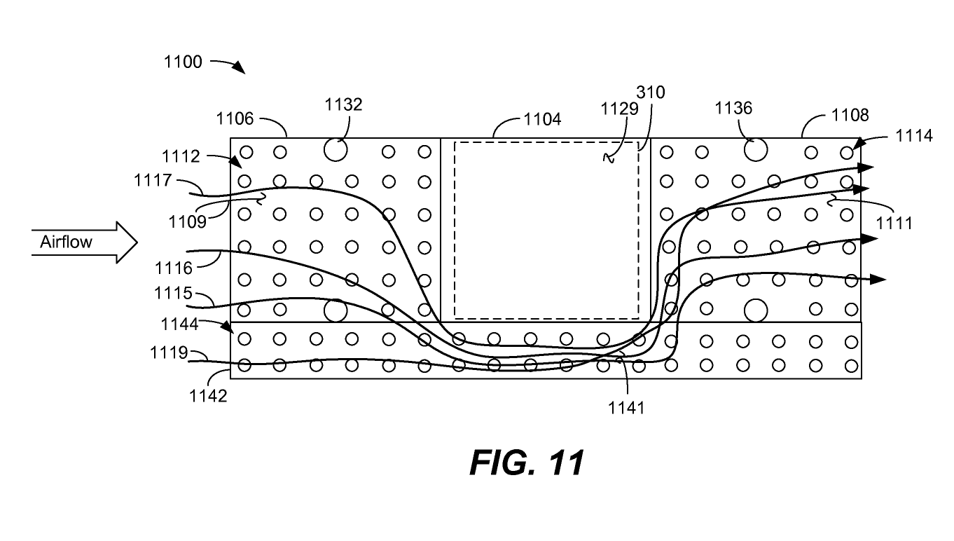

FIG. 11 is a diagram showing a plan view and airflow over and around an alternative embodiment of the heat sink of FIGS. 1 and 2. In an exemplary embodiment, heat sink 1100 comprises a central portion 1104 and extended portions 1106 and 1108. The heat sink 1100 also comprises additional extended portion 1142. The extended portion 1106 comprises heat dissipation elements 1112, the extended portion 1108 comprises heat dissipation elements 1114, and the extended portion 1142 comprises heat dissipation elements 1144. In an exemplary embodiment, the heat dissipation elements 1112, 114 and 1144 are implemented as substantially circular or round shaped “pins” or “posts” that extend upwardly from the surfaces 1109, 1111, and 1141, respectively, no further than a plane defined by an upper surface 1129 of the central portion 1104.

In an exemplary embodiment, one or more of the shape, location, orientation, structure and other physical attributes of the heat dissipation elements 1112, one or more of the shape, location, orientation, structure and other physical attributes of the heat dissipation elements 1114, and one or more of the shape, location, orientation, structure and other physical attributes of the heat dissipation elements 1144 causes air to flow through the heat dissipation elements 1112, around the central portion 1104, through the heat dissipation elements 1144, and through the heat dissipation elements 1114. An exemplary heat generating element 310 is shown for example of illustration. Heat can be transferred from the upper surface 312 of the heat generating element 310 to the heat sink 1100 as described above.

As described above, the air passing through the heat dissipation elements 1112, around the central portion 1104, through the heat dissipation elements 1144, and through the heat dissipation elements 1114 removes heat and therefore cools the central portion 1104, in turn removing heat from the heat generating element 310. In an exemplary embodiment, the heat dissipation elements 1112, 1114 and 1144 are located to promote airflow through the heat dissipation elements 1112, around the central portion 1104, through the heat dissipation elements 1144 and then through the heat dissipation elements 1114 such that even if air is impeded or prevented from flowing over the upper surface 1129, air still flows through the heat dissipation elements 1112, 1114 and 1144, thus maximizing the transfer of heat away from the heat generating element 310. In an exemplary embodiment, the heat dissipation elements 1112, 1114 and 1144 are located spaced away from the heat generating element 310 and extend upwardly no further than the plane defined by the upper surface 1129 of the central portion 1104. In an exemplary embodiment, the heat dissipation elements 1112, 1114 and 1144 maintain indirect contact with the heat generating element 310 in that the heat dissipation elements 1112, 1114 and 1144 do not directly contact or emanate from any surface of the heat generating element 310.

The bold arrows 1115, 1116 and 1117 illustrate exemplary airflow that can be directed across the heat sink 1100 and around the central portion 1104 by the heat dissipation elements 1112, 1114 and 1144. In an exemplary embodiment, the shape and location of the heat dissipation elements 1144 direct the airflow from the heat dissipation elements 1112 closely around the central portion 1104 and then toward the heat dissipation elements 1114 causing air to flow through the heat dissipation elements 1112, around the central portion 1104, through the heat dissipation elements 1144 and through the heat dissipation elements 1114. Moreover, the heat dissipation elements 1144 can also cause air that may not be directed toward the heat dissipation elements 1112, such as air flow shown by the bold arrow 1119, to be directed toward and then through the heat dissipation elements 1114. This additional airflow directed by the heat dissipation elements 1144 can further improve cooling provided by the heat sink 1100. The airflow can be as a result of forced air, such as from a cooling fan, or can be convective air flow caused by thermal differences in the vicinity of the heat sink 1100.

While various embodiments of the invention have been described, it will be apparent to those of ordinary skill in the art that many more embodiments and implementations are possible that are within the scope of this invention.

What is claimed is:

1. A heat sink, comprising:
a heat sink body having a central portion and at least a first extended portion; and
heat dissipation elements extending from at least the first extended portion, the heat dissipation elements extending no further than a plane formed by an upper surface of the central portion, the central portion having a recess configured to receive a heat generating element, the central portion being free of heat dissipation elements.

2. The heat sink of claim 1, wherein the heat dissipation elements are configured to direct airflow through the heat dissipation elements and around the central portion.

3. The heat sink of claim 1, wherein the heat dissipation elements are curved elements.

4. The heat sink of claim 3, wherein a plurality of curved elements have curves of different shape.

5. The heat sink of claim 4, wherein the plurality of curved elements are configured in rows having multiple curved elements with the same shape.

6. The heat sink of claim 4, wherein the heat dissipation elements maintain indirect contact with the heat generating element.

7. The heat sink of claim 6, wherein the indirect contact comprises contact between the central portion, the first extended portion and a second extended portion.

8. The heat sink of claim 1, further comprising at least one biasing element configured to apply downward pressure on the heat sink body such that the heat sink body is suspended over a substrate.

9. A heat sink, comprising:
a heat sink body having a central portion, a first extended portion, and a second extended portion; and
heat dissipation elements extending from a surface of the first extended portion and a surface of the second extended portion, the central portion having a recess configured to receive a heat generating element, the central portion being free of heat dissipation elements.

10. The heat sink of claim 9, wherein the heat dissipation elements are configured to direct airflow through the heat dissipation elements and around the central portion.

11. The heat sink of claim 9, wherein the heat dissipation elements are curved elements.

12. The heat sink of claim 11, wherein a plurality of curved elements have curves of different shape.

13. The heat sink of claim 12, wherein the plurality of curved elements are configured in rows having multiple curved elements having the same shape.

14. The heat sink of claim 12, wherein the heat dissipation elements maintain indirect contact with the heat generating element.

15. The heat sink of claim 14, wherein the indirect contact comprises contact between the central portion and the first and second extended portions.

16. The heat sink of claim 9, further comprising at least one biasing element configured to apply downward pressure on the heat sink body such that the heat sink body is suspended over a substrate.

17. A method for removing heat, comprising:
directing airflow through heat dissipation elements and around a central portion of a heat sink using the heat dissipation elements extending from at least a first extended portion of the heat sink, the heat dissipation elements extending no further than a plane formed by an upper surface of the central portion, the central portion having a recess configured to receive a heat generating element, the central portion being free of heat dissipation elements.

18. The method of claim 17, wherein the heat dissipation elements are curved elements.

19. The method of claim 18, wherein a plurality of curved elements have curves of different shape.

20. The method of claim 19, wherein the plurality of curved elements are configured in rows having multiple curved elements with the same shape.

21. The method of claim 19, wherein the heat dissipation elements maintain indirect contact with the heat generating element.

22. The method of claim 21, wherein the indirect contact comprises contact between the central portion and the first and second extended portions.
